(19) United States
(12) Patent Application Publication
(10) Pub. No.: US 2025/0383395 A1
(43) Pub. Date: Dec. 18, 2025

(54) NON-CONTACT DETECTION SYSTEM AND METHOD FOR USING THE SAME

(71) Applicant: UNIKORN SEMICONDUCTOR CORPORATION, Hsinchu (TW)

(72) Inventors: Po-Kai Chiang, Hsinchu (TW); Chen-Kang Chiu, Hsinchu (TW); Tai-I Yang, Hsinchu (TW); Cheng-Yi Lin, Hsinchu (TW); Hsin-Chung Hsu, Hsinchu (TW); Hao-Ming Ku, Hsinchu (TW)

(21) Appl. No.: 18/745,250

(22) Filed: Jun. 17, 2024

(51) Int. Cl. G01R 31/265; G01R 31/26

(52) U.S. Cl. CPC G01R 31/2656; G01R 31/2635

(57) ABSTRACT

A method for non-contact detection. The method includes providing a semiconductor device. The semiconductor device has an epitaxial stack, a first electrode and a second electrode connected to the epitaxial stack. The method further includes applying a microwave to the first electrode to cause the semiconductor device to emit light and detecting the light emitted from the semiconductor device.

### BACKGROUND OF THE INVENTION

### Field of the Invention

The present disclosure relates to a detection system, and, in particular, to a non-contact detection system and a method for using the same.

### Description of the Related Art

In the fabrication process of light-emitting diode (LED), various optical and other measurement tests are employed to ensure quality and reproducibility of LED. The electroluminescence (EL) detection method currently in use involves using a probe directly contacting electrodes of LED during measurement. However, as the testing quantities increase, challenges related to low detection reliability may arise due to probe blunting. In addition, when the tip area of a probe is greater than the area of the electrode, not only does it lead to a failure of lighting up the LED, but it also elevates the risk of potential damage to the LED. Moreover, when measuring different chips of the wafer, the probe needs to be moved and repositioned. The processes of probe movement and repositioning are time-consuming and often determine the detection rate. Besides, the frequent replacement of probes also consumes cost.

### BRIEF SUMMARY OF THE INVENTION

An embodiment of the present disclosure provides a method for non-contact detection. The method includes providing a semiconductor device. The semiconductor device has an epitaxial stack, a first electrode and a second electrode connected to the epitaxial stack. The method further includes applying a microwave to the first electrode to cause the semiconductor device to emit light and detecting the light emitted from the semiconductor device.

An embodiment of the present disclosure provides a non-contact detection system. The non-contact detection system includes a semiconductor device, a microwave device, and a light collecting device. The microwave device is used for applying a microwave to the semiconductor device to cause the semiconductor device to emit light. The light collecting device is used for detecting the light emitted from the semiconductor device.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIG. 1 is a schematic diagram of a semiconductor device during non-contact detection, in accordance with some embodiments.

FIG. 2 is a schematic diagram of a semiconductor device during non-contact detection, in accordance with some other embodiments.

FIG. 3 is a schematic diagram of a semiconductor device during non-contact detection, in accordance with some further embodiments.

FIG. 4 is a schematic diagram of a non-contact detection system, in accordance with some embodiments.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “below,” “above,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

The present disclosure provides a non-contact detection system and a method using the same. The probes used in the existing contact-based detection method can be omitted to reduce costs and save time spent on probe movement and positioning. In addition, the non-contact detection method also enhances measurement stability and accuracy, thereby increasing the detection reliability while preventing potential damage to semiconductor devices. Moreover, the ability to test multiple semiconductor devices simultaneously contributes to the overall boost in detection speed.

Some embodiments of the disclosure are described. Additional operations can be provided before, during, and/or after the stages described in these embodiments. Some of the stages that are described can be replaced or eliminated for different embodiments. Additional features can be added to the semiconductor device. Some of the features described below can be replaced or eliminated for different embodiments. Although some embodiments are discussed with operations performed in a particular order, these operations may be performed in another logical order.

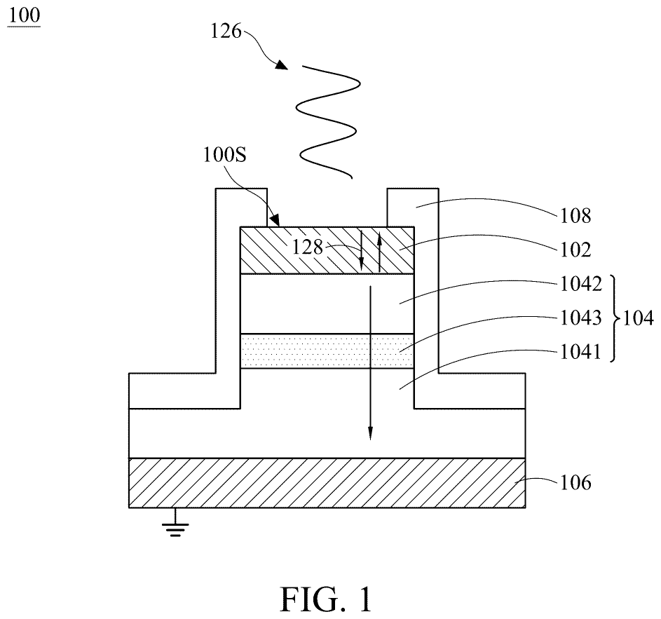

FIG. 1 is a schematic diagram of a semiconductor device 100 during non-contact detection, in accordance with some embodiments. It should be noted that the following embodiments can replace, recombine, and combine features in several different embodiments to complete other embodiments without departing from the spirit of the present disclosure.

The semiconductor device 100 includes a light-emitting device, such as a light emitting diode (LED), an edge emitting laser (EEL), a vertical-cavity surface emitting lasers (VCSEL), and a photonic crystal surface emitting laser (PCSEL). The LED includes a micro light emitting diode (micro LED), an organic light emitting diode (OLED), or a mini light emitting diode (mini LED). In the following disclosure, the semiconductor device 100 will be exemplified by utilizing micro-LEDs to illustrate the embodiments, but the present disclosure is not limited thereto.

In an embodiment, the semiconductor device 100 is a light-emitting diode and includes a first electrode 102, an epitaxial stack 104, and a second electrode 106. The first electrode 102 and the second electrode 106 are electrically connected to the epitaxial stack 104. In an embodiment, the first electrode 102 and the second electrode 106 are disposed on opposite sides of the epitaxial stack 104 and the semiconductor device 100 represents a vertical-type LED. The structure of the semiconductor device 100 is simplified, and additional features such as buffer layers, blocking layers and contact layers are omitted for the sake of simplicity.

In some embodiments, the epitaxial stack 104 includes a first semiconductor structure 1041, an active region 1043, and a second semiconductor structure 1042 sequentially formed on the second electrode 106. Both the first semiconductor structure 1041 and the second semiconductor structure 1042 can have either a single-layer or multi-layer structure (multi-layer indicating two or more layers). The first semiconductor structure 1041 and the second semiconductor structure 1042 have different conductive types or are doped with different elements for providing either electrons or holes. The first semiconductor structure 1041 has a first conductivity type, and the second semiconductor structure 1042 has a second conductivity type different from the first conductivity type. For example, the first semiconductor structure 1041 can be p-type, and the second semiconductor structure 1042 can be n-type, or vice versa. The active region 1043 is formed between the first semiconductor structure 1041 and the second semiconductor structure 1042. Driven by a current, electrons and holes are combined in the active region 1043 to convert electrical energy into optical energy for illumination.

The wavelength of the emitted light can be tuned by adjusting one or more layers within the epitaxial stack 104. The material of the epitaxial stack 104 may include aluminum gallium indium phosphide (AlGaInP) series, aluminum gallium indium nitride (AlGaInN) series or aluminum gallium indium arsenide (AlGaInAs) series or indium gallium arsenide phosphide (InGaAsP). The epitaxial stack 104 may include single heterostructure (SH), double heterostructure (DH), double-side double heterostructure (DDH) or multi-quantum well (MWQ). Specifically, the active region 1043 can be intrinsic, p-type or n-type semiconductor. When the material of the active region 1043 is InGaP or AlInGaP, the active region 1043 can emit red light with a wavelength between 610 nm and 700 nm, or emit yellow light or green light with a wavelength between 510 nm and 600 nm. When the material of the active region 1043 is InGaN, the active region 1043 can emit blue light or deep blue light with a wavelength between 400 nm and 490 nm, emit green light with a wavelength between 490 nm and 550 nm or emit red light with a wavelength between 560 nm and 650 nm. When the material of the active region 1043 is AlGaN or AlGaInN, the active region 1043 can emit ultraviolet light with a wavelength between 250 nm and 400 nm. When the material of the active region 1043 is InGaAs, InGaAsP, AlGaAs, or AlGaInAs, the active region 1043 can emit infrared light with a wavelength between 700 nm and 1700 nm.

In some embodiments, the epitaxial stack 104 may be formed on a growth substrate (not shown) by epitaxial growth. The growth substrate may include a sapphire (Al₂O₃) substrate, a gallium nitride (GaN) substrate, a silicon carbide (SiC) substrate, an aluminum nitride (AlN) substrate or a gallium arsenide (GaAs) substrate. In some embodiments, the growth substrate may be a patterned substrate, that is, the surface of the growth substrate facing the epitaxial stack 104 is patterned. In any embodiments of the present disclosure, the epitaxial growth processing may include metal organic chemical vapor deposition (MOCVD), hydride vapor deposition (HVPE), molecular beam epitaxy (MBE), physical vapor deposition (PVD) or liquid-phase epitaxy (LPE) method. In other embodiment, the semiconductor device 100 further includes a base between the first semiconductor structure 1041 and the second electrode 106, and the base can be the growth substrate or a replacing substrate.

In some embodiments, the first electrode 102 covers the upper surface of the epitaxial stack 104 and is electrically connected to the second semiconductor structure 1042. The second electrode 106 deposits under the first semiconductor structure 1041 and is electrically connected to the first semiconductor structure 1041. The first electrode 102 and the second electrode 106 can include the same material or different materials. In the embodiment, the first electrode 102 and the second electrode 106 may include a transparent conductive oxide, metal or alloy. More specifically, the transparent conductive oxide includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), or indium zinc oxide (IZO). The metal includes chromium (Cr), titanium (Ti), tungsten (W), gold (Au), aluminum (Al), indium (In), tin (Sn), nickel (Ni), platinum (Pt), silver (Ag), molybdenum (Mo), silicon (Si), copper (Cu) or tantalum (Ta). or an alloy or stack thereof. The alloy includes the two or more metals mentioned above. In the embodiment, the first electrode 102 includes different material from that of the second electrode 106. More specifically, the first electrode 102 includes transparent conductive oxide and the second electrode 106 includes metal or alloy. In other embodiments, the first electrode 102 and the second electrode 106 includes same material, such as the transparent conductive oxide.

In some embodiments, the semiconductor device 100 further includes a passivation layer 108 for preventing external moisture or contaminations from entering the epitaxial stack 104. The passivation layer 108 is formed on one or more surfaces of the epitaxial stack 104, and optionally covers a part of the first electrode 102. The passivation layer 108 may include organic material or inorganic material. Organic material includes benzocyclobutene (BCB), perfluorocyclobutane (PFCB), epoxy resin, acrylic resin, cycloolefin polymer (COC), polymethyl methacrylate (PMMA), polyethylene terephthalate (PET), polycarbonate (PC), polyetherimide or fluorocarbon polymer. Inorganic material includes silicone, glass, aluminum oxide (Al₂O₃), silicon nitride (SiNₓ), silicon oxide (SiOₓ), titanium oxide (TiOₓ) or magnesium fluoride (MgFₓ).

The passivation layer 108 can be formed by various deposition techniques, followed by patterning to expose the first electrode 102. The deposition techniques may include chemical vapor deposition (CVD), physical vapor deposition (PVD) or atomic layer deposition (ALD).

Still referring to FIG. 1, in an embodiment, a microwave 126 is applied to the first electrode 102 to induce an induced current 128, causing the semiconductor device 100 to emit light. In this embodiment, the second electrode 106 is electrically grounded.

Specifically, the current 128 is initiated by the first electrode 102, rectified spontaneously by the epitaxial stack 104, and grounded electrically through the second electrode 106. In other words, after the microwave 126 is irradiated onto the semiconductor device 100, the induced current 128 passes through the semiconductor device 100, thus causing the epitaxial stack 104 to emit light. It should be noted that the induced current induced by the first electrode 102 is bidirectional and may transition to unidirectional after being rectified by the epitaxial stack 104.

In an embodiment, the microwave 126 includes a frequency ranging from 2 GHz to 6 GHz, such as 3 GHz, 4 GHz, or 5 GHz, and a wavelength ranging from 1.5 μm to 10 μm such as 2 μm, 5 μm, or 8 μm.

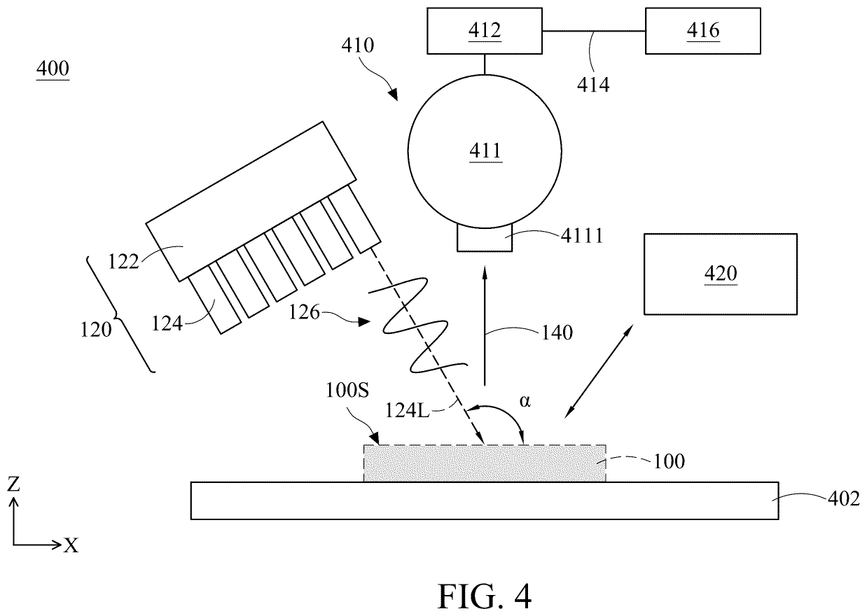

After applying the microwave, the light-emitting characteristics of the semiconductor device 100 are assessed by a light collecting device 410 (as illustrated in FIG. 4) that detects the light emitted from the semiconductor device 100. Since the probe used in the conventional detection method is omitted, this approach enhances detection speed, measurement stability, and accuracy while preventing the semiconductor device 100 from potential damage.

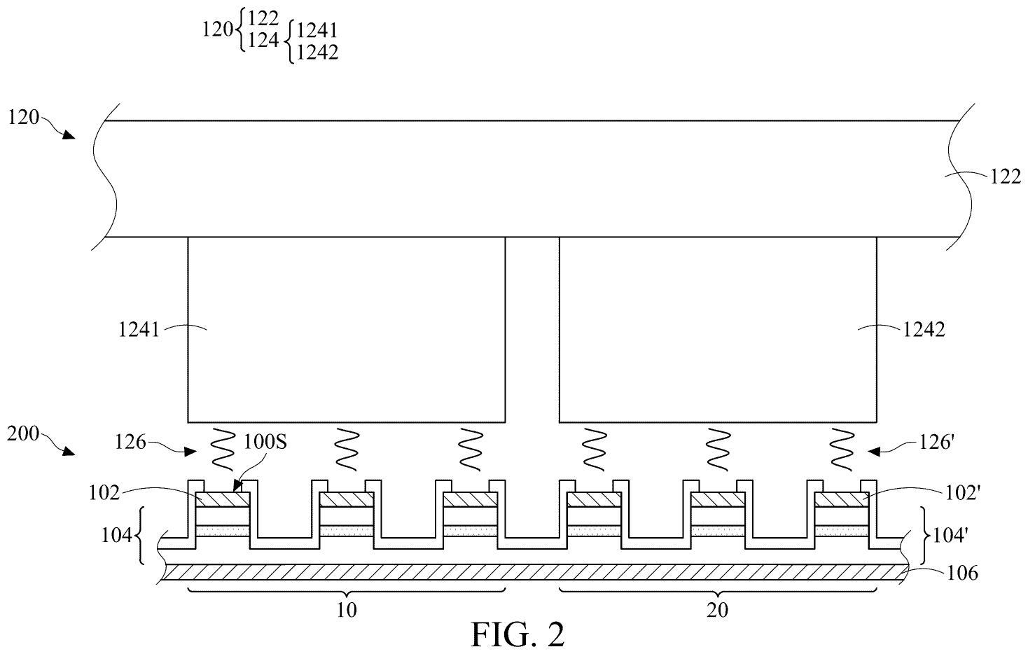

FIG. 2 is a schematic diagram of a semiconductor device 200 during non-contact detection, in accordance with some other embodiments. In an embodiment, the semiconductor device 200 is a wafer having a plurality of light-emitting diodes. The semiconductor device 200 includes a first set 10 of epitaxial stacks 104 and first electrodes 102 respectively disposed on the epitaxial stacks 104, and a second set 20 of epitaxial stacks 104′ and first electrodes 102′ respectively disposed on the epitaxial stacks 104′. A common second electrode 106 locates under the epitaxial stacks 104, 104′. The first electrodes 102, 102′, epitaxial stacks 104, 104′, and the second electrode 106 are similar to those described in connection with FIG. 1, and their descriptions will not be repeated herein for brevity. Note that although FIG. 2 only shows six of epitaxial stacks on the wafer, the present disclosure is not limited thereto. The number and arrangement of the epitaxial stack 104, 104′ and the first electrode 102, 102′ can be configured according to actual requirements. In addition, in some embodiments, the first set 10 of epitaxial stacks 104 and the second set 20 of epitaxial stacks 104′ may be disposed on two separate second electrodes (not shown). In the embodiment, multiple light-emitting diodes can be simultaneously measured.

In an embodiment, the microwave 126 is applied to the first electrode 102, 102′ of the plurality of light-emitting diodes by a microwave device 120, and the lights emitted from the plurality of light-emitting diodes are detected. In some embodiments, the microwave device 120 includes a microwave generator 122 for generating the microwave 126, 126′ and a waveguide element 124 for transmitting the microwave 126 to the semiconductor device 200.

In some embodiments, the waveguide element 124 includes a first waveguide tube 1241 and a second waveguide tube 1242 as shown in FIG. 2. The first waveguide tube 1241 can transmit the microwave 126 to a first set 10 of the epitaxial stacks 104, and the second waveguide tube 1242 can transmit the microwave 126′ to a second set 20 of the epitaxial stacks 104′. The frequency or the wavelength of the microwave 126 can be the same with that of the microwave 126′. In other embodiment, the frequency or the wavelength of the microwave 126 can be different from that of the microwave 126′.

As shown in FIG. 2, in some embodiments, the microwave device 120 may have two waveguide tubes (such as the first waveguide tube 1241 and the second waveguide tube 1242) transmitting the microwave 126, 126′ to three of the epitaxial stacks 104, 104′, respectively. In other embodiments, the microwave device 120 may have a single waveguide tube transmitting the microwave 126 to a single epitaxial stack 104. The quantity and arrangement of the waveguide element 124 can be configured according to the dimension of the wafer to be tested and the desired measure of efficiency. In general, the number of the epitaxial stacks 104, 104′ that can be simultaneously measured depends on the dimension of the waveguide element 124.

This approach enables the simultaneous detection of the light-emitting properties of multiple light-emitting diodes across the entire wafer by incorporating multiple waveguide tubes, thereby increasing the detection speed.

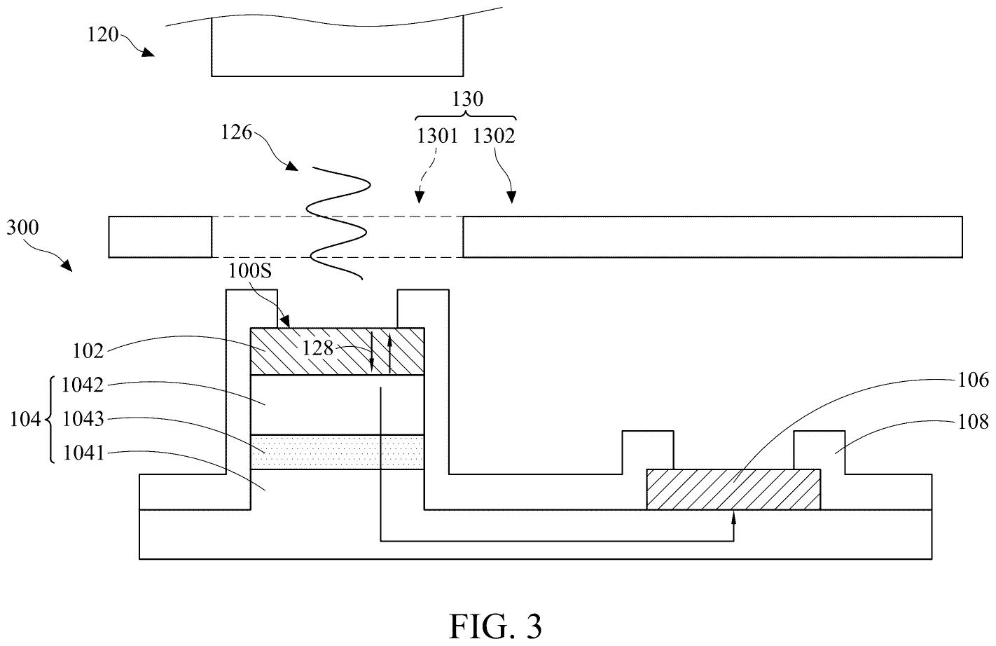

FIG. 3 is a schematic diagram of a semiconductor device 300 during non-contact detection, in accordance with some further embodiments. The semiconductor device 300 in FIG. 3 is similar to the semiconductor device 100 in FIG. 1, except that the first electrode 102 and the second electrode 106 are disposed on the same side of the first semiconductor structure 1041 to represent a horizontal-type LED. More specifically, the first electrode 102 locates on the second semiconductor structure 1042, and the second electrode 106 locates on the first semiconductor structure 1041 in the embodiment.

In an embodiment, a shielding element 130 is disposed between the semiconductor device 100 and the microwave device 120 for preventing the microwave 126 from reaching the second electrode 106. In some embodiments, the shielding element 130 includes a transmitting portion 1301 (indicated by a dash line) aligned with the first electrode 102 and a shielding portion 1302 (indicated by a solid line) for protecting the second electrode 106 from the microwave 126. In a top view, the transmitting portion 1301 is surrounded by the shielding portion 1302. In some embodiments, the shielding element 130 is a quartz plate and the shielding portion 1302 is made by covering the upper surface of the quartz plate with an opaque material that does not allow the transmission of microwaves.

In some embodiment, the microwave 126 passes through the transmitting portion 1301 of the shielding element 130 to the first electrode 102. The microwave 126 applied to the first electrode 102 induces the induced current 128. This induced current 128 is initiated by the first electrode 102, rectified spontaneously by the epitaxial stack 104, and grounded electrically through the second electrode 106. In other words, after the microwave 126 is irradiated onto the semiconductor device 100, the induced current 128 passes through the semiconductor device 100, thus causing the epitaxial stack 104 to emit light.

Methods or features that are the same or similar to those in the previous embodiments are designated the same reference numbers, and their details will not be repeated herein for brevity.

FIG. 4 is a schematic diagram of a non-contact detection system 400, in accordance with some embodiments. It should be noted that the non-contact detection system 400 is merely illustrative and is not intended to limit the present disclosure to what is explicitly illustrated therein. For the sake of simplicity, some reference numbers of components or features illustrated therein may be omitted to avoid obscuring other components or features for ease of depicting the figures.

In an embodiment, the non-contact detection system 400 includes a microwave device 120 and a light collecting device 410. In an embodiment, the non-contact detection system 400 further includes a stage 402. The stage 402, such as a chuck, is used for placing the semiconductor device 100 thereon, and the light collecting device 410 is disposed above the stage 402. In other embodiments, the light collecting device 410 is disposed below the stage 402, and the stage 402 has high transmittance to the light emitted by the semiconductor device 100.

In an embodiment, the semiconductor device 100 includes an incident surface 100S and the microwave 126 is irradiated onto the semiconductor device 100 by the waveguide tube 124. The waveguide tube 124 includes an extension line 124L. An incident angle α is defined as an angle between the extension line 124L of the waveguide tube 124 and the incident surfaces 100S of the semiconductor device 100. The incident angle α may range from 45° to 135° such as 60°, 90°, and 120°. In the embodiment shown in FIG. 2, the incident surface 100S can be an upmost surface of the first electrode 102.

In an embodiment where the incident angle α is about 90°, the microwave device 120 and the light collecting device 410 overlap in a vertical direction Y. In another embodiment, where the incident angle α is greater or smaller than 90°, the microwave device 120 and the light collecting device 410 do not overlap in the vertical direction Y.

The light collecting device 410 is configured to detect the light 140 emitted from the semiconductor device 100. In some embodiments, the light collecting device 410 includes a light collecting element 411, which is typically an integrating sphere, and the light collecting element 411 includes a light collecting port 4111 aligned to the incident surface 100S of the semiconductor device 100.

In an embodiment, the non-contact detection system 400 further includes a signal-amplifying device 412 electrically connected to the light collecting device 410 and configured to amplify an optical signal collected by the light collecting device 410. In an embodiment, the non-contact detection system 400 further includes an optical splitter 416 configured to measure a wavelength of the light 140. The optical splitter 416 is coupled to the light collecting device 410 through an optical fiber 414. In an embodiment, the non-contact detection system 400 further includes an electrical measurement device 420 for testing the semiconductor device 100. The electrical measurement device 420 may be contact form or non-contact form.

In summary, the present disclosure provides a method for non-contact detection and a non-contact detection system in which the probes used in the existing detection method can be omitted to reduce costs and save detection time spent on probe movement and positioning. In addition, it also enhances measurement stability and accuracy, thereby increasing the detection reliability while preventing potential damage to semiconductor devices. Moreover, the ability to test multiple semiconductor devices simultaneously contributes to the overall boost in detection speed.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for non-contact detection, comprising:
providing a semiconductor device, the semiconductor device having an epitaxial stack, a first electrode, and a second electrode, wherein the first electrode and the second electrode being connected to the epitaxial stack;
applying a microwave to the first electrode to cause the semiconductor device to emit light; and
detecting the light emitted from the semiconductor device.

2. The method for non-contact detection of claim 1, wherein the semiconductor device is a light-emitting diode.

3. The method for non-contact detection of claim 1, wherein the second electrode is grounded.

4. The method for non-contact detection of claim 1, wherein the microwave comprising a frequency ranging from 2 GHz to 6 GHz and a wavelength ranging from 1.5 μm to 10 μm.

5. The method for non-contact detection of claim 1, further comprising providing a microwave device having a waveguide tube, and the microwave is applied to the first electrode by the waveguide tube.

6. The method for non-contact detection of claim 1, wherein the semiconductor device is a wafer having a plurality of light-emitting diodes.

7. The method for non-contact detection of claim 6, wherein the microwave is applied to the plurality of light-emitting diodes, and the lights emitted from the plurality of light-emitting diodes are detected.

8. A non-contact detection system, comprising:
a semiconductor device;
a microwave device for applying a microwave to the semiconductor device to cause the semiconductor device to emit light; and
a light collecting device for detecting the light emitted from the semiconductor device.

9. The non-contact detection system of claim 8, wherein the microwave device comprises a waveguide element.

10. The non-contact detection system of claim 8, further comprising a stage for placing the semiconductor device, wherein the light collecting device is disposed above the stage.

11. The non-contact detection system of claim 8, wherein the microwave device and the light collecting device overlap in a vertical direction.

12. The non-contact detection system of claim 8, wherein the microwave device and the light collecting device do not overlap in a vertical direction.

13. The non-contact detection system of claim 9, wherein the waveguide element comprises a waveguide tube.

14. The non-contact detection system of claim 13, wherein the waveguide tube comprises an extension line, and an incident angle is defined as an angle between the extension line of the waveguide tube and the first electrode, and the incident angle ranges from 45° to 135°.

15. The non-contact detection system of claim 8, further comprising a signal-amplifying device electrically connected to the light collecting device.

16. The non-contact detection system of claim 8, further comprising an optical splitter coupling to the light collecting device.

17. The non-contact detection system of claim 8, further comprising an electrical measurement device for testing the semiconductor device.

18. The non-contact detection system of claim 8, wherein the first electrode and the second electrode are disposed on opposite sides of the epitaxial stack.

19. The non-contact detection system of claim 8, wherein the first electrode and the second electrode are disposed on a same side of the epitaxial stack.

20. The non-contact detection system of claim 8, further comprising a shielding element between the semiconductor device and the microwave device.
